(19) United States
(12) Patent Application Publication
(10) Pub. No.: US 2018/0187302 A1
(43) Pub. Date: Jul. 5, 2018

(54) MEASUREMENT ASSEMBLY FOR MEASURING A DEPOSITION RATE AND METHOD THEREFORE

(71) Applicants: Jose Manuel DIEGUEZ-CAMPO, Hanau (DE); Andreas LOPP, Freigericht-Somborn (DE); Uwe SCHÜSSLER, Aschaffenburg (DE); Stefan BANGERT, Steinau (DE); Applied Materials, Inc., Santa Clara, CA (US)

(72) Inventors: Jose Manuel DIEGUEZ-CAMPO, Hanau (DE); Andreas LOPP, Freigericht-Somborn (DE); Uwe SCHÜSSLER, Aschaffenburg (DE); Stefan BANGERT, Steinau (DE)

(21) Appl. No.: 15/572,585

(22) PCT Filed: Sep. 21, 2015
(86) PCT No.: PCT/EP2015/071608

§ 371 Date: Nov. 8, 2017

(51) Int. Cl. C23C 14/54; G01N 29/24; G01N 29/02; C23C 14/24

(52) U.S. Cl. CPC C23C 14/546; G01N 29/2443; G01N 2291/0256; C23C 14/24; G01N 29/022

(57) ABSTRACT

A measurement assembly for measuring a deposition rate of an evaporated material is described. The measurement assembly includes an oscillation crystal for measuring the deposition rate, a measurement outlet for providing evaporated material to the oscillation crystal, and a magnetic closing mechanism configured for opening and closing the measurement outlet by magnetic force.

### TECHNICAL FIELD

The present disclosure relates to a measurement assembly for measuring a deposition rate of an evaporated material, an evaporation source for evaporation of material, a deposition apparatus for applying material to a substrate and a method for measuring a deposition rate of an evaporated material. The present disclosure particularly relates to a measurement assembly for measuring a deposition rate of an evaporated organic material and a method therefore. Further, the present disclosure particularly relates to devices including organic materials therein, e.g. an evaporation source and a deposition apparatus for organic material.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not involve a back light. Therefore, the energy consumption of OLED displays is considerably less than that of traditional LCD displays. Further, the fact that OLEDs can be manufactured onto flexible substrates results in further applications.

The functionality of an OLED depends on the coating thickness of the organic material. This thickness has to be within a predetermined range. In the production of OLEDs, the deposition rate at which the coating with organic material is effected is controlled to lie within a predetermined tolerance range. In other words, the deposition rate of an organic evaporator has to be controlled thoroughly in the production process.

Accordingly, for OLED applications but also for other evaporation processes, a high accuracy of the deposition rate over a comparably long time is needed. There is a plurality of measurement systems for measuring the deposition rate of evaporators available. However, these measurement systems suffer from either insufficient accuracy and/or insufficient stability over the desired time period.

Accordingly, there is a continuing demand for providing improved deposition rate measurement systems, deposition rate measurement methods, evaporators and deposition apparatuses.

### SUMMARY

In view of the above, a measurement assembly for measuring a deposition rate of an evaporated material, an evaporation source, a deposition apparatus and a method for measuring a deposition rate of an evaporated material according to the independent claims are provided. Further advantages, features, aspects and details are apparent from the dependent claims, the description and drawings.

According to one aspect of the present disclosure, a measurement assembly for measuring a deposition rate of an evaporated material is provided. The measurement assembly includes an oscillation crystal for measuring the deposition rate, a measurement outlet for providing evaporated material to the oscillation crystal, and a magnetic closing mechanism configured for opening and closing the measurement outlet by magnetic force.

According to another aspect of the present disclosure, an evaporation source for evaporation of material is provided. The evaporation source includes an evaporation crucible, wherein the evaporation crucible is configured to evaporate a material; a distribution pipe with one or more outlets provided along the length of the distribution pipe for providing evaporated material, wherein the distribution pipe is in fluid communication with the evaporation crucible; and a measurement assembly according to any embodiment described herein.

According to a further aspect of the present disclosure, a deposition apparatus for applying material to a substrate in a vacuum chamber at a deposition rate is provided. The deposition apparatus includes at least one evaporation source according to embodiments described herein.

According to yet another aspect of the present disclosure, a method for measuring a deposition rate of an evaporated material is provided. The method includes evaporating a material; applying a first portion of the evaporated material to a substrate; diverting a second portion of the evaporated material to an oscillation crystal; and measuring the deposition rate by using the measurement assembly according to embodiments described herein.

The disclosure is also directed to an apparatus for carrying out the disclosed methods including apparatus parts for performing the methods. The method may be performed by way of hardware components, a computer programmed by appropriate software, by any combination of the two or in any other manner. Furthermore, the disclosure is also directed to operating methods of the described apparatus. The disclosure includes a method for carrying out every function of the apparatus.

### BRIEF DESCRIPTION OF THE DRAWINGS

So that the manner in which the above recited features of the disclosure described herein can be understood in detail, a more particular description, briefly summarized above, may be had by reference to embodiments. The accompanying drawings relate to embodiments of the disclosure and are described in the following:

FIG. 1 shows a schematic side view of a measurement assembly for measuring a deposition rate of an evaporated material according to embodiments described herein, wherein the measurement outlet is in an open state;

FIG. 2 shows a schematic side view of a measurement assembly according to FIG. 1, wherein the measurement outlet is in a closed state;

FIG. 3A shows a schematic side view of a measurement assembly for measuring a deposition rate of an evaporated material according to further embodiments described herein, wherein the measurement outlet is in an open state;

FIG. 3B shows a schematic side view of a measurement assembly according to FIG. 3A, wherein the measurement outlet is in a closed state;

FIG. 4 shows a schematic side view of a measurement assembly for measuring a deposition rate of an evaporated material according to further embodiments described herein;

FIGS. 5A to 5C show schematic side views of different embodiments of a magnetic closing element for the measurement assembly according to embodiments described herein;

FIGS. 6A and 6B show schematic side views of an evaporation source according to embodiments described herein;

FIG. 7 shows a perspective view of an evaporation source according to embodiments described herein;

FIG. 8 shows a schematic top view of a deposition apparatus for applying material to a substrate in a vacuum chamber according to embodiments described herein; and

FIG. 9 shows a block diagram illustrating a method for measuring a deposition rate of an evaporated material according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. In the following, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

In the present disclosure, the expression “oscillation crystal for measuring the deposition rate” may be understood as an oscillation crystal for measuring a mass variation of deposited material on the oscillation crystal per unit area by measuring the change in frequency of an oscillation crystal resonator. In particular, in the present disclosure an oscillation crystal may be understood as a quartz crystal resonator. More particularly, an “oscillation crystal for measuring the deposition rate” may be understood as a quartz crystal microbalance (QCM).

In the present disclosure, a “measurement outlet” may be understood as an opening or aperture, through which evaporated material can be provided to a measurement device, e.g. an oscillation crystal. Further, in the present disclosure, a “measurement outlet” may be understood as an opening or aperture which is provided in a wall, particularly a backside wall, of a distribution pipe of an evaporation source. In particular, a “measurement outlet” may provide a passage for evaporated material from a distribution pipe of a deposition source to a measurement side of the distribution pipe. The “measurement side” may be understood as the side of the distribution pipe at which the measurement is carried out, particularly by using an oscillation crystal for measuring the deposition rate. For example, the “measurement side” may be at the backside of the distribution pipe.

In the present disclosure, a “magnetic closing mechanism” may be understood as a mechanism which is configured for closing and opening an aperture, for example a measurement outlet. In particular, a “magnetic closing mechanism” may be understood as a mechanism in which magnetic forces are employed for closing and opening the measurement outlet.

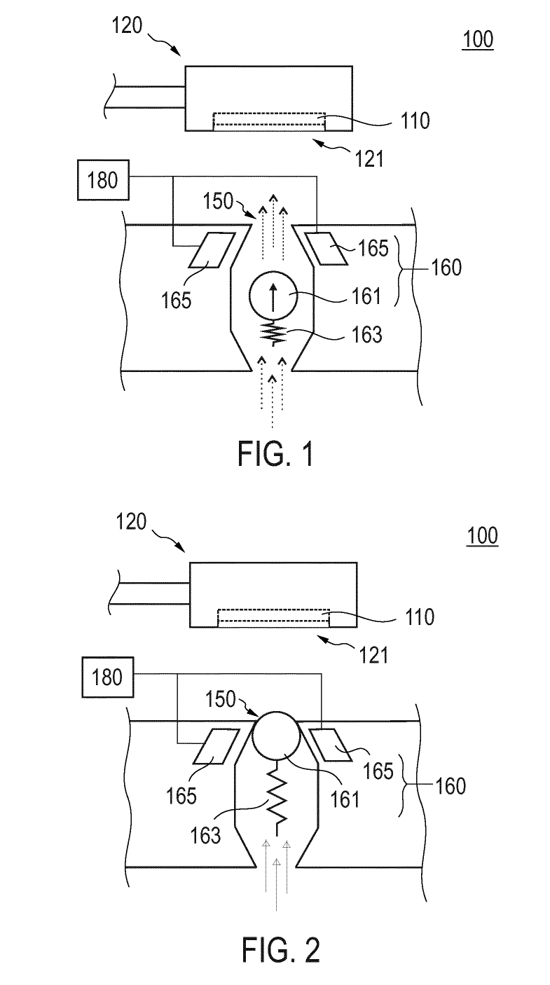

With exemplary reference to FIG. 1, a measurement assembly 100 for measuring a deposition rate of an evaporated material according to embodiments described herein includes an oscillation crystal 110 for measuring the deposition rate, a measurement outlet 150 for providing evaporated material to the oscillation crystal 110, and a magnetic closing mechanism 160. The magnetic closing mechanism 160 is configured for opening and closing the measurement outlet 150 by magnetic force.

By providing a measurement assembly having a magnetic closing mechanism as described herein, the measurement outlet can be closed in a quick and efficient manner. For example, the measurement outlet can be closed in a time interval between a first measurement and a second measurement. Accordingly, in a time interval between a first measurement and a second measurement, the oscillation crystal may be protected from evaporated material. Further, the amount of evaporated material on the oscillation crystal may be minimized to the actual amount needed for measuring the deposition rate of the evaporated material which may be beneficial for prolonging the lifetime of the oscillation crystal. Accordingly, embodiments of the measurement assembly as described herein may provide for high quality deposition rate measurements because the oscillation crystal may be carried out for a longer time compared to a configuration in which the oscillation crystal is permanently exposed to the evaporated material. Additionally, by providing a closable measurement outlet, for example a closable nozzle, particle generation of evaporated material on the measurement side of the measurement assembly, i.e. the side at which the oscillation crystal is arranged, may be reduced or can even be avoided which can be beneficial for the accuracy of the deposition rate measurement. Accordingly, employing a measurement assembly for measuring a deposition rate according to embodiments described herein may be beneficial for high quality display manufacturing, particularly OLED manufacturing.

Further, according to embodiments which can be combined with other embodiments described herein, the measurement assembly 100 may include a holder 120 for holding the oscillation crystal 110. As exemplarily shown in FIG. 1, the oscillation crystal 110 may be arranged inside the holder 120. Further, a measurement opening 121 may be provided in the holder 120 for providing evaporated material access to the oscillation crystal 110 for measuring the deposition rate of the evaporated material. In particular, the measurement opening 121 may be configured and arranged such that evaporated material may be deposited on the oscillation crystal for measuring the deposition rate of the evaporated material. The dotted arrows in FIG. 1 schematically illustrate the path of evaporated material provided through the measurement outlet 150.

According to embodiments which can be combined with other embodiments described herein, the magnetic closing mechanism 160 may include a magnetic closing element 161 as exemplarily shown in FIGS. 1 to 4. For example, the magnetic closing element 161 may include at least one magnetic material selected from the group consisting of: ferromagnetic materials; particularly iron, nickel, cobalt, rare metal alloys and ferromagnetic alloys.

According to embodiments of the measurement assembly 100 as described herein, the magnetic closing element may be configured to be moved between an open state and a closed state of the measurement outlet 150. FIG. 1 shows a schematic side view of the measurement assembly 100 according to embodiments described herein, wherein the measurement outlet 150 is in an open state. FIG. 2 shows a schematic side view of a measurement assembly 100 according to FIG. 1, wherein the measurement outlet 150 is in a closed state. As exemplarily shown in FIG. 2, in the closed state of the measurement outlet 150 the magnetic closing element 161 may be at a position within the measurement outlet 150 at which the measurement outlet 150 is blocked by the magnetic closing element 161. Accordingly, the magnetic closing element 161 and the measurement outlet 150 may be configured such that the measurement outlet 150 can be sealed by the magnetic closing element 161. Accordingly, the path through the measurement outlet may be blocked for the evaporated material in a closed state of the measurement outlet.

According to embodiments which can be combined with other embodiments described herein, the magnetic closing mechanism 160 may include an electromagnetic arrangement 165, as exemplarily shown in FIGS. 1 and 2. The electromagnetic arrangement 165 is configured for exerting a magnetic force on the magnetic closing element 161 for moving the magnetic closing element 161 from an open state into a closed state of the measurement outlet 150. As exemplarily shown in FIG. 1, the electromagnetic arrangement 165 may be arranged around the measurement outlet 150. For example, the electromagnetic arrangement 165 may be arranged at a position of the measurement outlet which is located close to the measurement side.

According to embodiments which can be combined with other embodiments described herein, a holding element 163 may be provided for holding the magnetic closing element 161 in an open position. With exemplary reference to FIG. 1, the holding element 163 may be an elastic element, such as a spring. The holding element 163 may be connected to the magnetic closing element 161. Further, the holding element 163 may be connected to an interior wall of the passage of the measurement outlet 150. Accordingly, in the case that the electromagnetic arrangement 165 is switched on to exert a magnetic force on the magnetic closing element 161, the magnetic closing element may move towards the position of the electromagnetic arrangement 165 resulting in a closure of the measurement outlet 150, as exemplarily shown in FIG. 2. From FIGS. 1 and 2 the skilled person understands that, when the electromagnetic arrangement 165 is switched off, the holding element 163 may exert a force on the magnetic closing element 161 such that the magnetic closing element 161 moves back to its initial position, for example in the open state position as shown in FIG. 1. In particular, the holding element 163 may exert an elastic force on the magnetic closing element 161, for example a spring force stored in the elastic elongated holding element 163 in a closed state position of the magnetic closing element 161, as exemplarily shown in FIG. 2.

According to embodiments which can be combined with other embodiments described herein, the magnetic closing element 161 can be in the form of a variety of geometric shapes. In particular, the magnetic closing element may include an aerodynamic, laminar-promoting, and or turbulence reducing shape. For example, the magnetic closing element 161 may have a spherical-like shape, which is configured for sealing the measurement outlet 150 in a closed state of the measurement outlet 150, as exemplarily shown in FIG. 2. Alternatively, the magnetic closing element 161 may include an ellipsoidal shape, a cone-like shape, a double cone-like shape, a pyramidal shape, a diamond-like shape or any other suitable shape. Illustrative examples of various geometric shapes which may be used for a magnetic closing element 161 according to embodiments described herein are shown in FIGS. 5A to 5C. For example, FIG. 5A shows a magnetic closing element 161 having a cone-like or conus-like shape, FIG. 5B shows a magnetic closing element 161 having a double cone-like or diamond like shape, and FIG. 5C shows a magnetic closing element 161 having an ellipsoidal shape. It is to be understood that according to embodiments described herein, the geometry of the closing element 161 and the geometry of the measurement outlet 150 are configured and adapted to each other, such that in a closed position of the closing element 161 the measurement outlet 150 may be sealed.

As exemplarily shown in FIGS. 1 to 4, according to embodiments which can be combined with other embodiments described herein, the electromagnetic arrangement may be connected to a power source 180. The power source can include a variable voltage power source such as a DC power source, an AC power source, and the like. For example, when the electromagnetic arrangement is energized by the power source 180, the electromagnetic arrangement may magnetically bias the magnetic closing element 161 such that the magnetic closing element 161 resultantly moves towards the position at which the energized electromagnetic arrangement is arranged. A movement of the magnetic closing element 161 is exemplarily indicated in FIG. 1 by the arrow on the magnetic closing element 161.

According to embodiments which can be combined with other embodiments described herein, the electromagnetic arrangement 165 may be configured as a ring magnet arranged around the measurement outlet 150, as exemplarily shown in FIGS. 1 and 2. Alternatively, the electromagnet arrangement 165 may include one or more electromagnetic elements which are arranged around the measurement outlet 150. The one or more electromagnetic elements can be connected to the power source 180 for energizing the one or more electromagnetic elements.

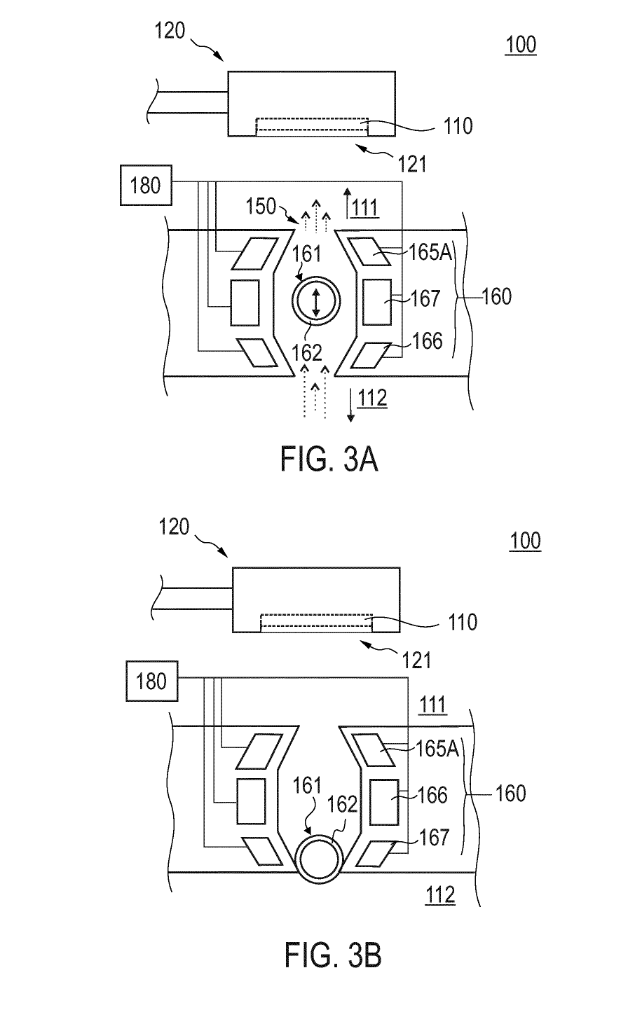

According to embodiments which can be combined with other embodiments described herein, the magnetic closing element 161 may include a coating 162, as exemplarily shown in FIGS. 3A, 3B, 4 and 5A-5C. The coating 162 may include a material which is non-reactive with respect to the evaporated material to be measured. In particular, the coating may include a material which is non-reactive with respect to evaporated organic material. For example, the coating 162 may include at least one material selected from the group consisting of: titanium (Ti); ceramics, particularly silicon oxide (SiO2), aluminum oxide (Al2O3), magnesium oxide (MgO), zirconium oxide ZrO2. Accordingly, accumulation of evaporated material on the magnetic closing element 161 may be reduced or even avoided.

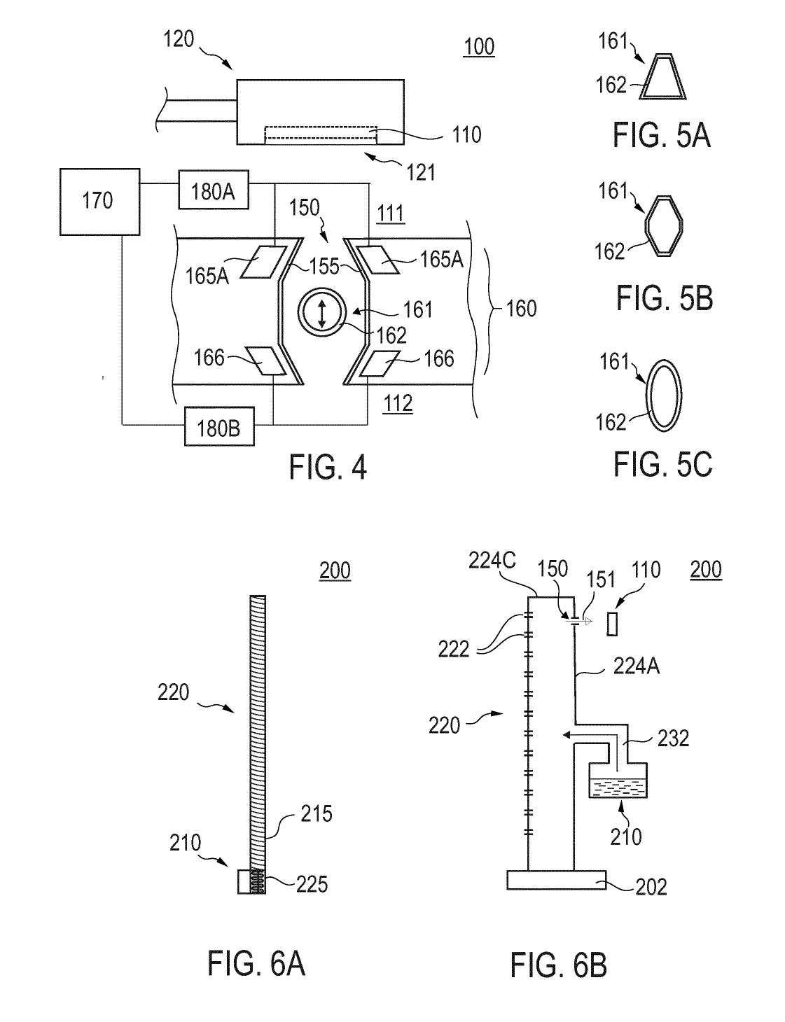

With exemplary reference to FIG. 4, according to embodiments which can be combined with other embodiments described herein, the magnetic closing mechanism 160 may include a first electromagnet arrangement 165A and a second electromagnet arrangement 166. The first electromagnetic arrangement 165A may be arranged at a position of the measurement outlet which is located close to the measurement side 111 of the measurement outlet 150 and the second electromagnet arrangement 166 may be arranged at a position of the measurement outlet which is located close to an opposing side 112 of the measurement side 111. Accordingly, the passage of evaporated material may be blocked by the magnetic closing element 161 in a first position, as exemplarily shown in FIG. 1, or in a second position as exemplarily shown in FIG. 3B. Accordingly, the magnetic closing element may be configured to be movable between an open position (exemplarily shown in FIG. 3A) and a first closed position (exemplarily shown in FIG. 1) or a second closed position (exemplarily shown in FIG. 3B). Such a possible movement of the magnetic closing element between two different closed positions is exemplarily illustrated in FIG. 3A by the double sided arrow on the magnetic closing element 161.

Further, according to embodiments which can be combined with other embodiments described herein, a third electromagnetic arrangement 167 may be provided which is arranged between the first electromagnetic arrangement 165A and the second electromagnet arrangement 166, as exemplarily shown in FIGS. 3A and 3B. For example, the third electromagnetic arrangement 167 may be used for moving the magnetic closing element from a first closed position or a second closed position into an open position as shown in FIG. 3A. For example, when the third electromagnetic arrangement is energized by the power source 180, the third electromagnetic arrangement 167 may magnetically bias the magnetic closing element 161 such that the magnetic closing element 161 resultantly moves towards the position at which the third electromagnetic arrangement is arranged. Accordingly, the third electromagnetic arrangement 167 may be used to open a closed measurement outlet as well as to hold the closing element in an open position such that an open state of the measurement outlet can be maintained.

With exemplary reference to FIGS. 3A and 3B, the first electromagnetic arrangement 165A, the second electromagnetic arrangement 166 and the third electromagnetic arrangement 167 may be connected to a power source 180. Alternatively, each of the first electromagnetic arrangement 165A, the second electromagnetic arrangement 166 and the third electromagnetic arrangement 167 may be connected to a separate power source (not shown). It is to be understood, that a power source as described herein may be used to energize the respective electromagnetic arrangement to which the power source is connected such that the respective electromagnetic arrangement may magnetically bias the magnetic closing element 161. Accordingly, the magnetic closing element may move towards the position at which the respective energized electromagnetic arrangement is arranged.

According to embodiments which can be combined with other embodiments described herein, the interior wall of the passage to the measurement outlet 150 may be configured to have an aerodynamic and/or laminar-promoting and/or turbulence reducing geometry. Further, the interior wall of the passage to the measurement outlet 150 may include a surface coating 155, as exemplary shown in FIG. 4. The surface coating 155 may include a material which is non-reactive with respect to the evaporated material, particularly non-reactive with respect to an evaporated organic material. For example, the surface coating 155 may include at least one material selected form the group consisting of: titanium (Ti); ceramics, particularly silicon oxide (SiO2), aluminum oxide (Al2O3), magnesium oxide (MgO), zirconium oxide ZrO2. Accordingly, accumulation of evaporated material on the interior wall of the passage of the measurement outlet 150 may be reduced or can be even avoided, which may be beneficial in order to avoid clogging of the measurement outlet 150.

According to embodiments which can be combined with other embodiments described herein, the measurement assembly 100 may include a control system 170 as exemplarily shown in FIG. 4. The control system 170 may be connected to the respective electromagnetic arrangement for generating a magnetic force acting on the magnetic closing element 161. For example, in the exemplary embodiment shown in FIG. 4 the control system 170 is connected to the first electromagnetic arrangement 165A and the second electromagnetic arrangement 166. Although not explicitly illustrated in FIGS. 1-3, the skilled person understands that the control system 170 may also be connected to the electromagnetic arrangement 165 shown in FIGS. 1 and 2 or to the first electromagnetic arrangement 165A, the second electromagnetic arrangement 166 and the third electromagnetic arrangement 167 shown in FIGS. 3A and 3B. As exemplarily shown in FIG. 4 the control system 170 may be connected to a power source for energizing the respective electromagnetic arrangement, e.g. a first power source 180A for energizing the first electromagnetic arrangement 165A and a second power source 180B for energizing the second electromagnetic arrangement 166. In particular, the control system 170 may control the power of the respective power source employed for energizing the respective electromagnetic arrangement. Accordingly, by controlling the power of the respective power source, a magnetic force generated by the respective electromagnetic arrangement may be adjusted which may be beneficial for controlling the switching time from a closed state of the measurement outlet to an open state of the measurement outlet and vice versa.

FIGS. 6A and 6B show schematic side views of an evaporation source 200 according to embodiments as described herein. According to embodiments, the evaporation source 200 includes an evaporation crucible 210, wherein the evaporation crucible is configured to evaporate a material. Further, the evaporation source 200 includes a distribution pipe 220 with one or more outlets 222 provided along the length of the distribution pipe for providing evaporated material, as exemplarily shown in FIG. 6B. According to embodiments, the distribution pipe 220 is in fluid communication with the evaporation crucible 210, for example by a vapor conduit 232, as exemplarily shown in FIG. 6B. The vapor conduit 232 can be provided to the distribution pipe 220 at the central portion of the distribution pipe or at another position between the lower end of the distribution pipe and the upper end of the distribution pipe. Further, the evaporation source 200 according to embodiments described herein includes a measurement assembly 100 according to embodiments described herein. Accordingly, an evaporation source 200 is provided for which the deposition rate can be measured with a high accuracy. Accordingly, employing an evaporation source 200 according to embodiments described herein may be beneficial for high quality display manufacturing, particularly OLED manufacturing.

As exemplarily shown in FIG. 6A, According to embodiments which can be combined with other embodiments described herein, the distribution pipe 220 may be an elongated tube including a heating element 215. The evaporation crucible 210 can be a reservoir for material, e.g. organic material, to be evaporated with a heating unit 225. For example, the heating unit 225 may be provided within the enclosure of the evaporation crucible 210. According to embodiments, which can be combined with other embodiments described herein, the distribution pipe 220 may provide a line source. For example, as exemplarily shown in FIG. 6B, a plurality of outlets 222, such as nozzles, can be arranged along at least one line. According to an alternative embodiment (not shown), one elongated opening, e.g. a slit, extending along the at least one line may be provided. According to some embodiments, which can be combined with other embodiments described herein, the line source may extend essentially vertically.

According to some embodiments, which can be combined with other embodiments described herein, the length of the distribution pipe 220 may correspond to a height of a substrate onto which material is to be deposited in a deposition apparatus. Alternatively, the length of the distribution pipe 220 may be longer than the height of the substrate onto which material is to be deposited, for example at least by 10% or even 20%. Accordingly, a uniform deposition at the upper end of the substrate and/or the lower end of the substrate can be provided. For example, the length of the distribution pipe 220 can be 1.3 m or above, for example 2.5 m or above.

According to embodiments, which can be combined with other embodiments described herein, the evaporation crucible 210 may be provided at the lower end of the distribution pipe 220, as exemplarily shown in FIG. 6A. The material, e.g. an organic material, can be evaporated in the evaporation crucible 210. The evaporated material may enter the distribution pipe 220 at the bottom of the distribution pipe and may be guided essentially sideways through the plurality of outlets 222 in the distribution pipe 220, e.g. towards an essentially vertical substrate. With exemplary reference to FIG. 6B, the measurement assembly 100 according to embodiments described herein may be provided at an upper portion, particularly at an upper end, of the distribution pipe 220.

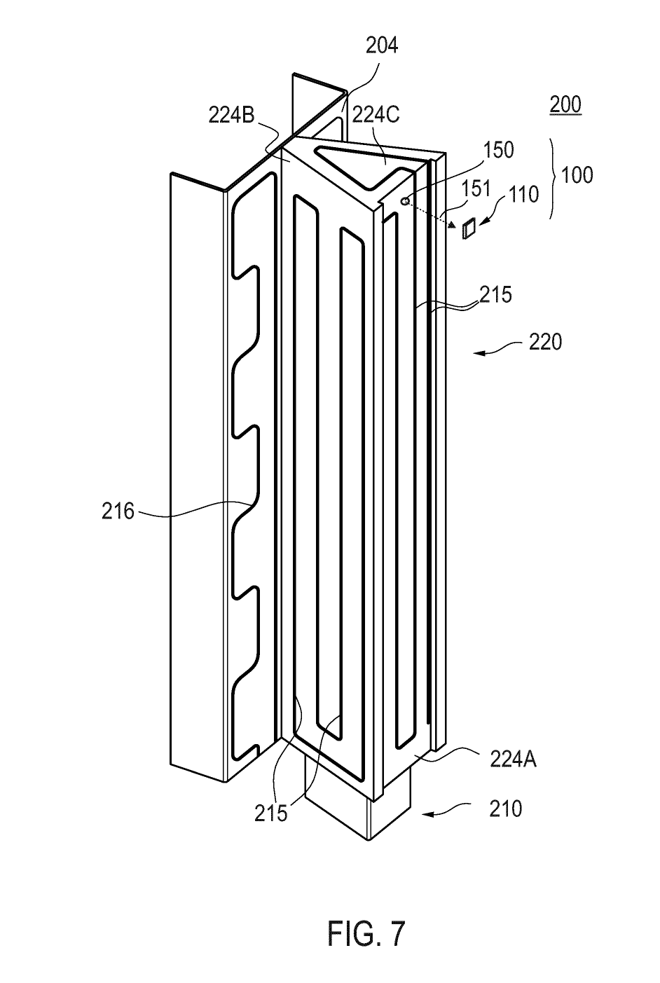

With exemplarily reference to FIG. 6B, according to embodiments which can be combined with other embodiments described herein, the measurement outlet 150 may be provided in a wall of the distribution pipe 220 or an end portion of the distribution pipe, for example in a wall at the backside 224A of the distribution pipe as exemplarily shown in FIGS. 6B and 7. Alternatively, the measurement outlet 150 may be provided in a top wall 224C of the distribution pipe 220. As exemplarily indicated by the arrow 151 in FIGS. 6B and 7 the evaporated material may be provided from the inside of the distribution pipe 220 through the measurement outlet 150 to the measurement assembly 100.

According to embodiments which can be combined with other embodiments described herein, the measurement outlet 150 may have an opening from 0.5 mm to 4 mm. The measurement outlet 150 may include a nozzle. For example, the nozzle may include an adjustable opening for adjusting the flow of evaporated material provided to the measurement assembly 100. In particular, the nozzle may be configured to provide a measurement flow selected from a range between a lower limit of 1/70 of the total flow provided by the evaporation source, particularly a lower limit of 1/60 of the total flow provided by the evaporation source, more particularly a lower limit of 1/50 of the total flow provided by the evaporation source and an upper limit of 1/40 of the total flow provided by the evaporation source, particularly an upper limit of 1/30 of the total flow provided by the evaporation source, more particularly an upper limit of 1/25 of the total flow provided by the evaporation source. For example, the nozzle may be configured to provide a measurement flow of 1/54 of the total flow provided by the evaporation source.

FIG. 7 shows a perspective view of an evaporation source 200 according to embodiments described herein. As exemplarily shown in FIG. 7, the distribution pipe 220 may be designed in a triangular shape. A triangular shape of the distribution pipe 220 may be beneficial in case two or more distribution pipes are arranged next to each other. In particular, a triangular shape of the distribution pipe 220 makes it possible to bring the outlets of neighboring distribution pipes as close as possible to each other. This allows for achieving an improved mixture of different materials from different distribution pipes, e.g. for the case of the co-evaporation of two, three or even more different materials. As exemplarily shown in FIG. 7, according to embodiments which can be combined with other embodiments described herein, the measurement assembly 100 may be provided in the hollow space of the distribution pipe 220, particularly at the upper end of the distribution pipe.

According to embodiments, which can be combined with other embodiments described herein, the distribution pipe 220 may include walls, for example side walls 224B and a wall at the backside 224A of the distribution pipe, e.g. an end portion of the distribution pipe, which can be heated by a heating element 215. The heating element 215 may be mounted or attached to the walls of the distribution pipe 220. According to some embodiments, which can be combined with other embodiments described herein, the evaporation source 200 may include a shield 204. The shield 204 may reduce the heat radiation towards the deposition area. Further, the shield 204 may be cooled by a cooling element 216. For example, the cooling element 216 may be mounted to the shield 204 and may include a conduit for cooling fluid.

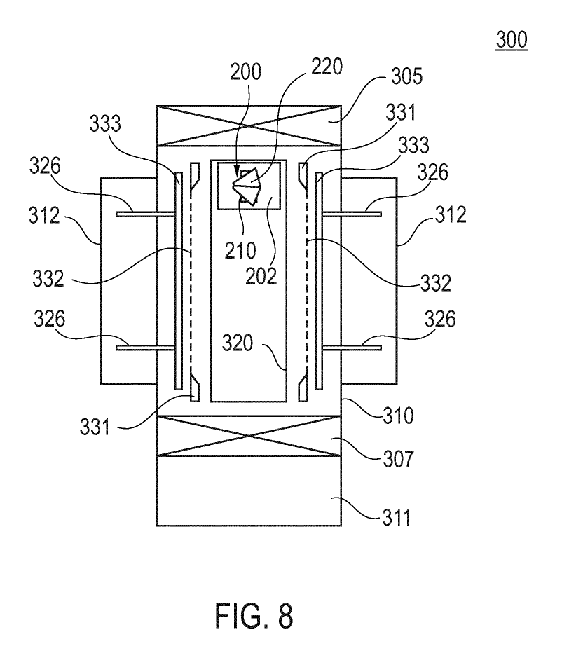

FIG. 8 shows a schematic top view of a deposition apparatus 300 for applying material to a substrate 333 in a vacuum chamber 310 according to embodiments described herein. According to embodiments which can be combined with other embodiments described herein, the evaporation source 200 as described herein may be provided in the vacuum chamber 310, for example on a track, e.g. a linear guide 320 or a looped track. The track or the linear guide 320 may be configured for a translational movement of the evaporation source 200. Accordingly, according to embodiments which can be combined with other embodiments described herein, a drive for the translational movement can be provided for the evaporation source 200, at the track and/or the linear guide 320, within the vacuum chamber 310. According to embodiments which can be combined with other embodiments described herein, a first valve 305, for example a gate valve, may be provided which allows for a vacuum seal to an adjacent vacuum chamber (not shown in FIG. 8). The first valve can be opened for transport of the substrate 333 or a mask 332 into the vacuum chamber 310 or out of the vacuum chamber 310.

According to some embodiments, which can be combined with other embodiments described herein, a further vacuum chamber, such as maintenance vacuum chamber 311 may be provided adjacent to the vacuum chamber 310, as exemplarily shown in FIG. 8. Accordingly, the vacuum chamber 310 and the maintenance vacuum chamber 311 may be connected with a second valve 307. The second valve 307 may be configured for opening and closing a vacuum seal between the vacuum chamber 310 and the maintenance vacuum chamber 311. The evaporation source 200 can be transferred to the maintenance vacuum chamber 311 while the second valve 307 is in an open state. Thereafter, the second valve 307 can be closed to provide a vacuum seal between the vacuum chamber 310 and the maintenance vacuum chamber 311. If the second valve 307 is closed, the maintenance vacuum chamber 311 can be vented and opened for maintenance of the evaporation source 200 without breaking the vacuum in the vacuum chamber 310.

As exemplarily shown in FIG. 8, two substrates may be supported on respective transportation tracks within the vacuum chamber 310. Further, two tracks for providing masks thereon can be provided. Accordingly, during coating the substrate 333 can be masked by respective masks. For example, the mask may be provided in a mask frame 331 to hold the mask 332 in a predetermined position.

According to some embodiments, which can be combined with other embodiments described herein, the substrate 333 may be supported by a substrate support 326, which can connect to an alignment unit 312. The alignment unit 312 may adjust the position of the substrate 333 with respect to the mask 332. As exemplarily shown in FIG. 8 the substrate support 326 may be connected to the alignment unit 312. Accordingly, the substrate may be moved relative to the mask 332 in order to provide for a proper alignment between the substrate and the mask during deposition of the material which may be beneficial for high quality display manufacturing. Alternatively or additionally, the mask 332 and/or the mask frame 331 holding the mask 332 can be connected to the alignment unit 312. Accordingly, either the mask 332 can be positioned relative to the substrate 333 or the mask 332 and the substrate 333 can both be positioned relative to each other.

As shown in FIG. 8, the linear guide 320 may provide a direction of the translational movement of the evaporation source 200. A mask 332 may be provided on both sides of the evaporation source 200. The masks may extend essentially parallel to the direction of the translational movement. Further, the substrates at the opposing sides of the evaporation source 200 can also extend essentially parallel to the direction of the translational movement. As exemplarily shown in FIG. 8, the evaporation source 200 provided in the vacuum chamber 310 of the deposition apparatus 300 may include a support 202 which may be configured for the translational movement along the linear guide 320. For example, the support 202 may support two evaporation crucibles and two distribution pipes 220 provided over the evaporation crucible 210. Accordingly, the vapor generated in the evaporation crucible can move upwardly and out of the one or more outlets of the distribution pipe.

Accordingly, embodiments of the deposition apparatus as described herein provide for improved quality display manufacturing, particularly OLED manufacturing.

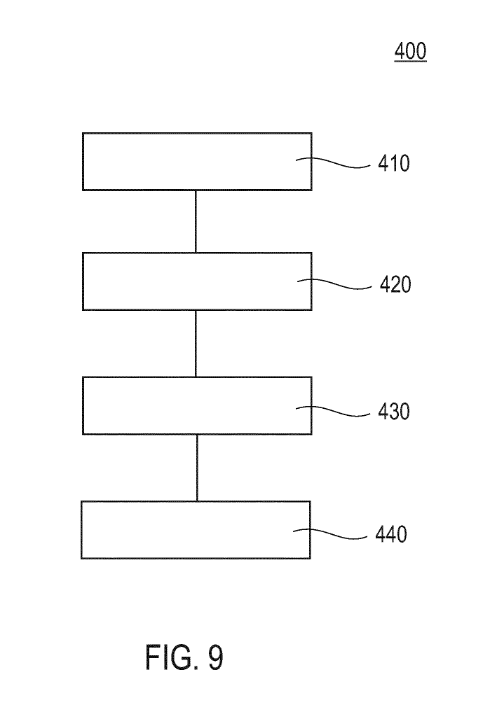

In FIG. 9 a block diagram illustrating a method for measuring a deposition rate of an evaporated material according to embodiments described herein is shown. According to embodiments, the method 400 for measuring a deposition rate of an evaporated material includes evaporating 410 a material, for example an organic material, applying 420 a first portion of the evaporated material to a substrate, diverting 430 a second portion of the evaporated material to an oscillation crystal 110, and measuring 440 the deposition rate by using a measurement assembly 100 according to embodiments described herein. Accordingly, by employing the method for measuring a deposition rate of an evaporated material according to embodiments described herein, the deposition rate may be measured highly accurately. In particular, by employing the method for measuring a deposition rate as described herein, the switching time from a closed stat of the measurement outlet to an open state of the measurement outlet and vice versa can be shorter than for conventional methods for measuring a deposition rate. Further, switching time may be controlled very precisely.

According to embodiments which can be combined with other embodiments described herein, evaporating 410 material incudes using an evaporation crucible 210 as described herein. Further, applying 420 a first portion of the evaporated material to a substrate may include using an evaporation source 200 according to embodiments described herein. According to embodiments which can be combined with other embodiments described herein, diverting 430 a second portion of the evaporated material to an oscillation crystal 110 may include using a measurement outlet 150 according to embodiments described herein. In particular, diverting 430 a second portion of the evaporated material to the oscillation crystal 110 may include providing a measurement flow selected from a range between a lower limit of 1/70 of the total flow provided by the evaporation source, particularly a lower limit of 1/60 of the total flow provided by the evaporation source, more particularly a lower limit of 1/50 of the total flow provided by the evaporation source and an upper limit of 1/40 of the total flow provided by the evaporation source, particularly an upper limit of 1/30 of the total flow provided by the evaporation source, more particularly an upper limit of 1/25 of the total flow provided by the evaporation source. For example, diverting 430 a second portion of the evaporated material to the oscillation crystal 110 may include providing a measurement flow of 1/54 of the total flow provided by the evaporation source.

According to embodiments which can be combined with other embodiments described herein, measuring 440 the deposition rate may include measuring the deposition rate with a time interval ΔT between a first measurement and a second measurement, wherein the measurement outlet 150 according to embodiments described herein is in a closed state between the first measurement and the second measurement. For example, the time interval ΔT between the first measurement and the second measurement, may be adjusted depending on the measured deposition rate. In particular, the dependence of the measured deposition rate may be a function of the deposition rate. For example, the first measurement and/or the second measurement may be carried out for 5 minutes or less, particularly for 3 minutes or less, more particularly for 1 minute or less.

According to embodiments which can be combined with other embodiments described herein time interval ΔT between a first measurement and a second measurement may be adjusted to be 50 minutes or less, particularly to be 35 minutes or less, more particularly to be 20 minutes or less. Accordingly, by adjusting the time interval between two measurements dependent on a function of the deposition rate, the measurement accuracy of the deposition rate may be increased. In particular, by adjusting the time interval between two measurements dependent on a function of the deposition rate, the lifetime of a deposition measurement device may be prolonged. In particular, the exposure of the measurement device to evaporated material for measuring the deposition rate of the evaporated material may be reduced to a minimum which can be beneficial for the overall lifetime of the measurement assembly, particularly lifetime of the oscillation crystal.

According to embodiments which can be combined with other embodiments described herein, during an initial adjustment of the preselected target deposition rate the time interval ΔT between a first measurement and a second measurement may be shorter compared to the time interval ΔT between a first measurement and a second measurement when the preselected target deposition rate has been reached. For example, during the initial adjustment of the preselected target deposition rate, the time interval ΔT between a first measurement and a second measurement may be 10 minutes or less, particularly may be 5 minutes or less, more particularly may be 3 minutes or less. When the preselected target deposition rate has been reached, the time interval ΔT between a first measurement and a second measurement may be selected from a range between a lower limit of 10 minutes, particularly a lower limit of 20 minutes, more particularly a lower limit of 30 minutes and an upper limit of 35 minutes, particularly an upper limit of 45 minutes, more particularly an upper limit of 50 minutes. In particular, when the preselected target deposition rate has been reached, the time interval ΔT between a first measurement and a second measurement may be 40 minutes. Accordingly, by employing the method for measuring a deposition rate of an evaporated material according to embodiments described herein, the amount of evaporated material on the oscillation crystal may be minimized to the actual amount needed for measuring the deposition rate of the evaporated material which may be beneficial for prolonging the lifetime of the oscillation crystal.

Accordingly, the measurement assembly for measuring a deposition rate of an evaporated material, the evaporation source, the deposition apparatus and the method for measuring a deposition rate according to embodiments described herein provide for improved deposition rate measurement and high quality display manufacturing, for example high quality OLED manufacturing.

1. A measurement assembly for measuring a deposition rate of an evaporated material, comprising:
a measurement device for measuring the deposition rate;
a measurement outlet for providing evaporated material to the measurement device; and
a magnetic closing mechanism configured for opening and closing the measurement outlet by magnetic force.

2. The measurement assembly according to claim 1, wherein the magnetic closing mechanism comprises a magnetic closing element configured to be moved between an open state and a closed state of the measurement outlet.

3. The measurement assembly according to claim 2, wherein the closing element comprises a coating of material which is non-reactive with respect to the evaporated material.

4. The measurement assembly according to claim 3, wherein the coating comprises at least one material selected form the group consisting of: titanium (Ti) and ceramics.

5. The measurement assembly according to claim 2, wherein the magnetic closing element comprises at least one ferromagnetic materials.

6. The measurement assembly according to claim 2, wherein the magnetic closing element comprises a shape selected from the group consisting of: a spherical-like shape, an ellipsoidal shape, a cone-like shape, a double cone-like shape, a pyramidal shape, a diamond-like shape or any combination thereof.

7. The measurement assembly according to claim 1, wherein the magnetic closing mechanism comprises an electromagnetic arrangement configured for exerting a magnetic force on the magnetic closing element.

8. The measurement assembly according to claim 7, further comprising a control system connected to the electromagnetic arrangement and configured for controlling the magnetic closing element between a closed state and an open state via the electromagnetic arrangement.

9. The measurement assembly according to claim 1, wherein the measurement outlet is a nozzle.

10. The measurement assembly according to claim 2, wherein the closing element comprises a coating of material which is non-reactive with respect to the evaporated material, the magnetic closing element comprises a spherical-like shape, the magnetic closing mechanism comprises an electromagnetic arrangement configured for moving the magnetic closing element between the open state and the closed state of the measurement outlet, and the measurement assembly further comprises a power source for energizing the electromagnetic arrangement.

11. An evaporation source for evaporation of material, comprising:
an evaporation crucible;
a distribution pipe with one or more outlets provided along the length of the distribution pipe in fluid communication with the evaporation crucible; and
a measurement assembly, the measurement assembly comprising:
a measurement device for measuring the deposition rate;
a measurement outlet for providing evaporated material to the measurement device; and
a magnetic closing mechanism configured for opening and closing the measurement outlet by magnetic force.

12. The evaporation source according to claim 11, wherein the measurement outlet and the measurement assembly are arranged at an end portion of the distribution pipe.

13. A deposition apparatus for applying material to a substrate in a vacuum chamber at a deposition rate, comprising at least one evaporation source, the at least one evaporation source comprising an evaporation crucible, wherein the evaporation crucible is configured to evaporate a material;
a distribution pipe with one or more outlets provided along the length of the distribution pipe for providing evaporated material, wherein the distribution pipe is in fluid communication with the evaporation crucible; and
a measurement assembly, the measurement assembly comprising:
a measurement device for measuring the deposition rate;
a measurement outlet for providing evaporated material to a measurement device; and
a magnetic closing mechanism configured for opening and closing the measurement outlet by magnetic force.

14. A method for measuring a deposition rate of an evaporated material, comprising:
evaporating a material;
applying a first portion of the evaporated material to a substrate;
selectively diverting a second portion of the evaporated material to a measurement device; and
measuring the deposition rate by using the measurement assembly, the measurement assembly comprising:
a measurement device for measuring the deposition rate;
a measurement outlet for providing evaporated material to the measurement device; and
a magnetic closing mechanism configured for opening and closing the measurement outlet by magnetic force.

15. The method according to claim 14, wherein measuring the deposition rate comprises measuring the deposition rate with a time interval ΔT between a first measurement and a second measurement.

16. The measurement assembly according to claim 1, wherein the measurement assembly comprises a holder for holding the measurement device, the holder comprising a measurement opening.

17. The measurement assembly according to claim 6, wherein the shape is configured for sealing the measurement outlet in a closed state of the measurement outlet.

18. The measurement assembly according to claim 7, wherein the electromagnetic arrangement is arranged around the measurement outlet.

19. The measurement assembly according to claim 7, wherein the electromagnetic arrangement comprises one or more electromagnetic elements which are arranged around the measurement outlet.

20. The measurement assembly according to claim 7, wherein the electromagnetic arrangement comprises a first electromagnetic arrangement arranged at a measurement side of the measurement outlet.

21. The measurement assembly according to claim 20, wherein the electromagnetic arrangement comprises a second electromagnetic arrangement arranged at an opposing side of the measurement side.

22. The measurement assembly according to claim 1, wherein the measurement outlet is configured for providing a measurement flow from 1/70 of a total flow provided by an evaporation source to 1/25 of the total flow provided by the evaporation source.

23. The method according to claim 15, wherein the measurement outlet is in a closed state between the first measurement and the second measurement.
